(19) United States
(12) Patent Application Publication
(10) Pub. No.: US 2004/0127027 A1
(43) Pub. Date: Jul. 1, 2004

(54) Method for forming titanium silicide contact of semiconductor device

(76) Inventors: Yoon-Jik Lee, Ichon-shi (KR); Hyun-Chul Sohn, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/639,002

(22) Filed: Aug. 11, 2003

(30) Foreign Application Priority Data
Dec. 30, 2002 (KR) 2002-86179

(51) Int. Cl. H01L 21/44

(52) U.S. Cl. 438/683

(57) ABSTRACT

The present invention is related to a method for forming a titanium silicide contact in a semiconductor device capable of minimizing consumptions of a silicon substrate and performing a low-temperature deposition through the use of an atomic layer deposition technique. The method includes the steps of: forming an inter-layer insulation layer on a silicon substrate; forming a contact hole exposing a portion of the silicon substrate by selectively etching the inter-layer insulation layer; forming a titanium silicide layer on the exposed portion of the silicon substrate by employing an atomic layer deposition technique using a source gas of titanium tetrachloride and a silicon-containing gas; forming a metal barrier layer on the resulting structure; and forming a contact plug by filling a conductive material into the contact hole and planarizing the deposited conductive material.

### FIELD OF THE INVENTION

The present invention relates to a method for forming a titanium silicide contact; and, more particularly, to a method for forming a titanium silicide layer for an ohmic contact through the use of an atomic layer deposition (ALD) technique.

### DESCRIPTION OF RELATED ARTS

In a semiconductor device, a wiring is to connect a bottom structure with an upper structure, and it is most important since it is a factor that determines a speed, yields and reliability of a semiconductor device. In case of a lowly integrated semiconductor device, a metal deposition in a contact hole for connecting wires is not a critical factor. However, an effective method for forming a contact is emphasized because the size of the contact decreases and simultaneously an aspect ratio also increases as a level of integration increases.

Therefore, prior to forming a contact plug, a wiring process is performed by adding silicide having a low resistivity, a high melting point and a good stability at a high temperature into a junction region with a silicon substrate.

FIGS. 1A to 1D are cross-sectional views showing a conventional method for forming a titanium silicide contact in a semiconductor device.

Referring to FIG. 1A, an inter-layer insulation layer 12 is formed on a substrate 11 and is then etched to form a contact hole 13 exposing an active region of the substrate 11.

Subsequent to the formation of the contact hole 13, a titanium silicide (TiSi₂) layer 14 is formed through a plasma enhanced chemical vapor deposition (PECVD) technique. At this time, titanium tetrachloride (TiCl₄) gas and hydrogen (H₂) gas are used to form a radio frequency (RF) plasma having a power of above 200 W to thereby proceed the above-mentioned deposition process. Herein, referring to FIG. 1B, the TiCl₄ gas is used as a source gas. Particularly, SiH₄ can be also added to the TiCl₄ source gas and H₂ gas. The titanium silicide layer 14 formed through the PECVD technique can be expressed by the following chemical equation.

TiCl₄+2H₂+2Si=TiSi₂+4HCl Eq. 1

According to the Eq. 1, a TiCl₄ molecule and H₂ molecules react with silicon (Si) originated from the silicon substrate 11 to form titanium silicide (TiSi₂) molecules. However, in practice, a high temperature of above about 800° C. is required to form the TiSi₂ molecules through a decomposition of the TiCl₄ molecule. Accordingly, the actual chemical reaction is different from the above chemical reaction obtained by employing the PECVD technique. That is, it is believed that the TiCl₄ molecule is decomposed to radicals of TiClₓ, where x is less than 4, through the use of the RF plasma and these radicals vigorously react with the silicon from the silicon substrate 11.

The above conventional PECVD technique has an advantage that a deposition temperature can be lowered by activating a reaction of the TiClₓ radicals with the silicon substrate 11. However, in this case, it is not the H₂ that causes a reduction of the TiClₓ radicals but silicon because the reaction between the TiClₓ radicals and the silicon provided from the silicon substrate 11 is too vigorous. As a result, the silicon substrate 11 is highly consumed. The reaction between the TiClₓ radicals and the silicon can be expressed as the following chemical equation.

4TiClₓ+(x+8)Si=4TiSi₂+xSiCl₄ Eq. 2

That is, in addition to the consumptions of the silicon for producing the TiSi₂, the silicon is also consumed to form silicon tetrachloride (SiCl₄). Thus, the consumptions of the silicon provided from the silicon substrate 11 are excessive, and this high consumptions results in an increase of leakage currents.

Referring to FIG. 1C, after the titanium silicide layer 14 formation, a titanium nitride (TiN) layer 15 is formed along a profile containing the contact hole 13 and the titanium silicide layer 14. Then, tungsten is deposited on the titanium nitride layer 15 through a chemical vapor deposition (CVD) technique until being filled into the contact hole 13. Referring to FIG. 1D, from this deposition of the tungsten, a contact plug 16 is then formed.

According to the above-described conventional method, there arises a problem that the consumptions of silicon are too extensive due to the reaction between the TiClₓ radicals and the silicon provided from the silicon substrate 11 for forming TiSi₂ and SiCl₄. This problem becomes more severe around a shallow junction. Also, as described previously, this high consumption of the silicon is a factor for causing leakage currents.

### SUMMARY OF THE INVENTION

It is, therefore, an object of the present invention to provide a method for forming a titanium silicide contact in a semiconductor device capable of minimizing silicon consumptions in the substrate and performing a deposition at a low temperature by employing an atomic layer deposition (ALD) technique that flows alternatively a source gas of TiCl₄ and a silicon-containing gas during a formation of a titanium silicide layer.

In accordance with an aspect of the present invention, there is provided a method for forming a titanium silicide contact in a semiconductor device, including the steps of: forming an inter-layer insulation layer on a silicon substrate; forming a contact hole exposing a portion of the silicon substrate by selectively etching the inter-layer insulation layer; forming a titanium silicide layer on the exposed portion of the silicon substrate by employing an atomic layer deposition (ALD) technique using a source gas of titanium tetrachloride (TiCl₄) and a silicon-containing gas; forming a metal barrier layer on the resulting structure; and forming a contact plug by filling a conductive material into the contact hole and planarizing the deposited conductive material.

### BRIEF DESCRIPTION OF THE DRAWING(S)

The above and other objects and features of the present invention will become apparent from the following description of the preferred embodiments given in conjunction with the accompanying drawings, in which:

FIGS. 1A to 1D are cross-sectional views showing a conventional method for forming a titanium silicide contact in a semiconductor device; and

FIGS. 2A to 2H are cross-sectional views showing a method for forming a titanium silicide contact in accordance with a preferred embodiment of the present invention.

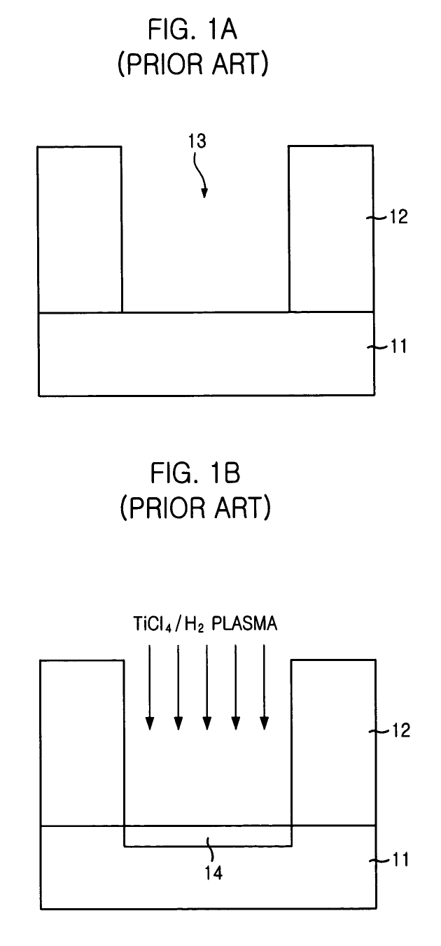

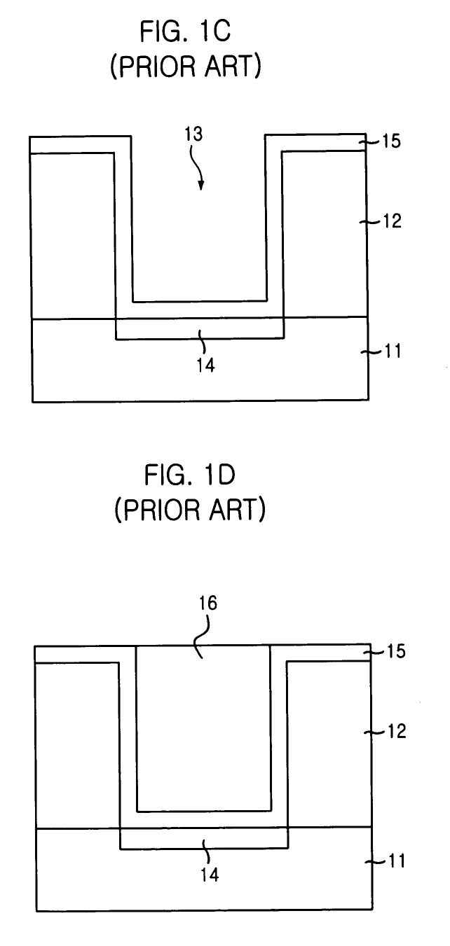

### DETAILED DESCRIPTION OF THE INVENTION

Hereinafter, with reference to the drawings, a method for forming a titanium silicide contact will be explained in detail.

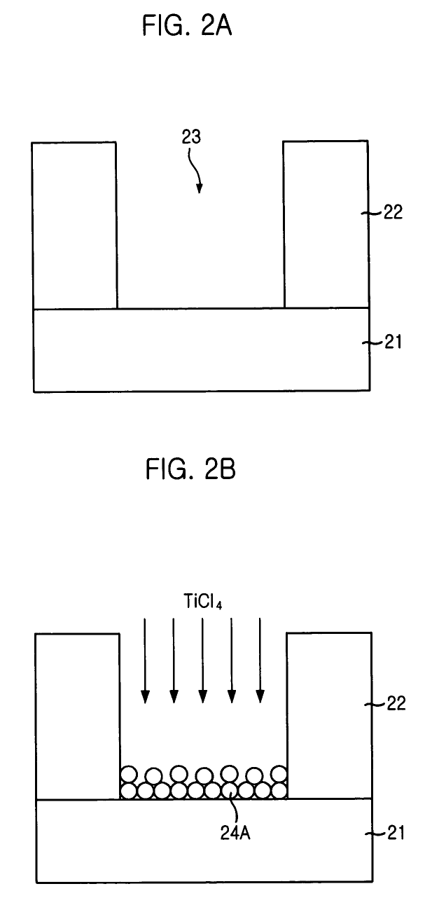

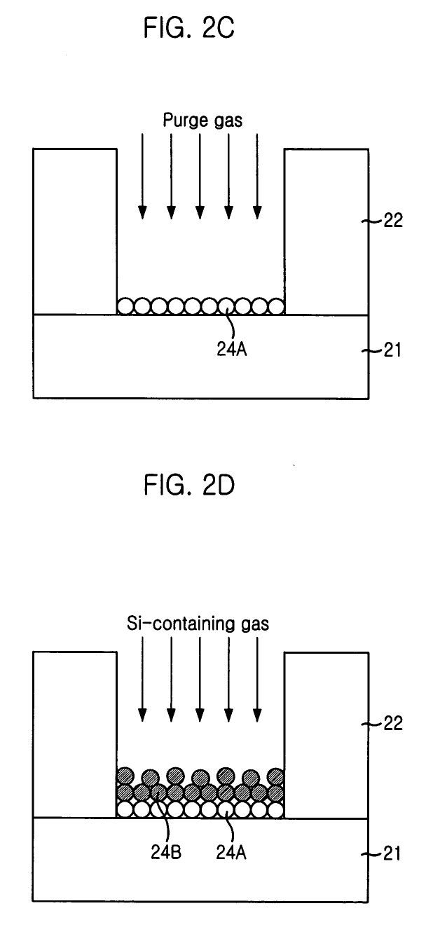

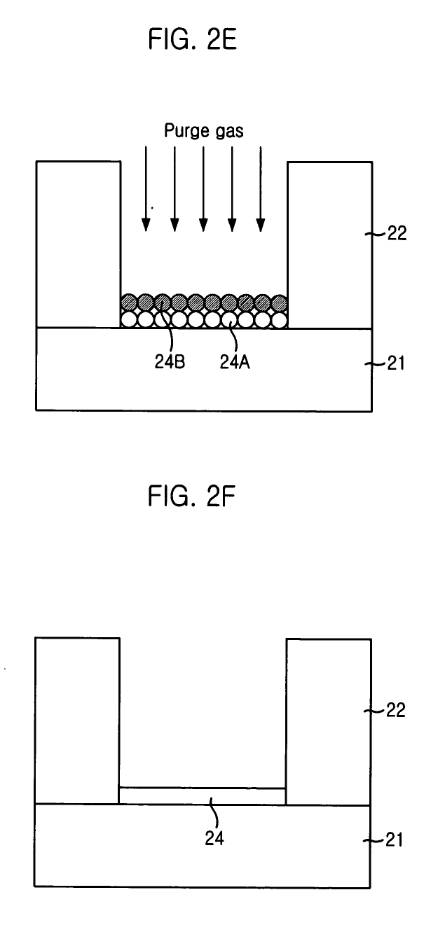

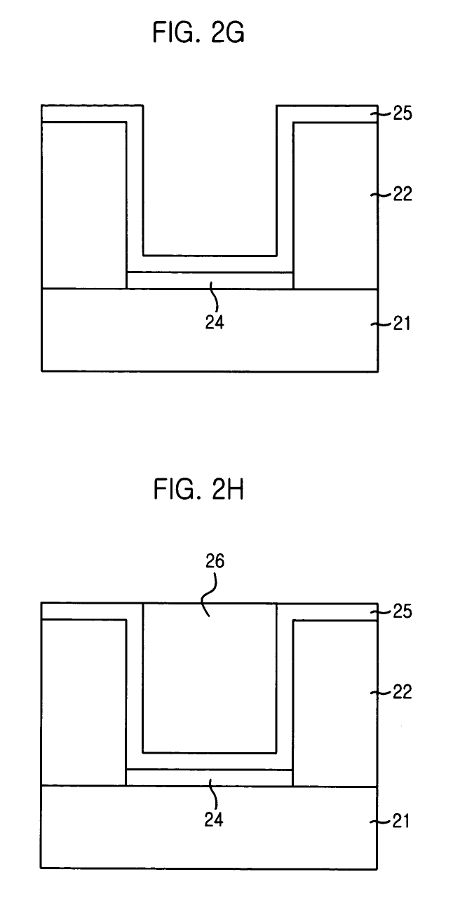

FIGS. 2A to 2H are cross-sectional views showing a method for forming a titanium silicide contact in accordance with a preferred embodiment of the present invention.

Referring to FIG. 2A, an inter-layer insulation layer 22 is deposited entirely on a surface of a silicon substrate 21 providing transistors. The inter-layer insulation layer 22 is then selectively etched to form a contact hole 23 exposing an active region of the silicon substrate 21.

Referring to FIG. 2B, the resulting structure is placed into an atomic layer deposition (ALD) chamber. Then, a source gas, which is TiCl₄, is flowed with a temperature of the silicon substrate 21 maintained in a range from about 500° C. to about 900° C. to form TiCl₄ molecules 24A adsorbed onto the exposed portion of the silicon substrate 21, i.e., the active region. At this time, the TiCl₄ source gas is flowed for approximately above 0.5 seconds to make a sufficient adsorption of the TiCl₄ molecules 24A onto the exposed portion of the silicon substrate 21.

Then, the TiCl₄ source gas is stopped flowing, and a purge gas is supplied into the ALD chamber for about 0.05 seconds to about 10 seconds to remove the remaining non-adsorbed molecules of the TiCl₄ molecules 24A. This purging process is illustrated in FIG. 2C.

As shown in FIG. 2D, after the removal of the non-adsorbed TiCl₄ molecules, a silicon-containing gas is flowed for a predetermined period to get silicon-containing gas molecules 24B are adsorbed onto a layer of the adsorbed TiCl₄ molecules 24A. At this time, SiH₄ gas is an example of the silicon-containing gas.

Subsequently, a purging process is performed to remove the remaining gases in the ALD chamber. At this time, an inert gas or H₂ gas is used as the purge gas for cleaning the ALD chamber. This purging process is shown in FIG. 2E.

The above-described processes illustrated from FIG. 2B to FIG. 2E are repeated until a titanium silicide layer 24 is formed with an intended thickness. The adsorbed TiCl₄ molecules 24A react with the adsorbed silicon-containing gas molecules 24A to thereby form the titanium silicide layer 24 on the active region of the silicon substrate 21. FIG. 2F shows the titanium silicide layer 24 formed by the above repeated processes.

At this time, during or after the formation of the titanium silicide layer 24 with use of the ALD technique, a plasma treatment using H₂ or SiH₄ gas is proceeded to reduce amounts of chloride. Also, after the titanium silicide layer 24 is formed through the ALD technique, a plasma treatment is performed again in an atmosphere of ammonia (NH₃) or nitrogen/hydrogen (N₂/H₂) to nitridated a surface of the titanium silicide layer 24.

As shown in FIG. 2G, a metal barrier layer 25 made of such material as titanium nitride (TiN) is formed on the above resulting structure. In more detail, the TiN barrier layer 25 is formed in an in-situ condition by using a low-pressure chemical vapor deposition (LPCVD) technique or an ALD technique.

Afterwards, such materials as tungsten (W), aluminum (Al), copper (Cu) having a good conductivity is deposited on the TiN barrier layer 25, and an etch-back process or a chemical mechanical polishing (CMP) process is subsequently performed to planarize the deposited material to a surface level of the TiN barrier layer 25 disposed over an upper part of the etched inter-layer insulation layer 22. From this CMP process or the etch-back process, a contact plug 26 is formed as described in FIG. 2H.

By following the preferred embodiment of the present invention, consumptions of the silicon substrate can be minimized by suppressing generations of TiClₓ radicals, where x is less than 4. The TiClₓ radical generations can be suppressed since a plasma is not used in the titanium silicide contact formation. Also, the consumptions of the silicon can be compensated by supplying the silicon-containing gas such as SiH4 gas during the formation of the titanium silicide layer. Furthermore, the titanium silicide layer can be reliably deposited with an intended thickness by employing the ALD technique, and thereby providing a good step-coverage.

While the present invention has been described with respect to certain preferred embodiments, it will be apparent to those skilled in the art that various changes and modifications may be made without departing from the scope of the invention as defined in the following claims.

What is claimed is:

1. A method for forming a titanium silicide contact in a semiconductor device, comprising the steps of:
(a) forming an inter-layer insulation layer on a silicon substrate;
(b) forming a contact hole exposing a portion of the silicon substrate by selectively etching the inter-layer insulation layer;
(c) forming a titanium silicide layer on the exposed portion of the silicon substrate by employing an atomic layer deposition (ALD) technique using a source gas of titanium tetrachloride (TiCl₄) and a silicon-containing gas;
(d) forming a metal barrier layer on the resulting structure; and
(e) forming a contact plug by filling a conductive material into the contact hole and planarizing the deposited conductive material.

2. The method as recited in claim 1, wherein the step
(c) includes further the steps of:
(c-1) performing an adsorption process for adsorbing TiCl₄ molecules onto the exposed portion of the silicon substrate by flowing a source gas of TiCl₄;
(c-2) performing a purging process for removing the remaining TiCl₄ source gas from the ALD chamber;
(c-3) performing an adsorption process for adsorbing a silicon-containing gas onto the adsorbed TiCl₄ molecules by flowing the silicon-containing gas for a predetermined period; and
(c-4) performing a purging process for removing the remaining gas from the ALD chamber.

3. The method as recited in claim 2, wherein the titanium silicide layer is formed until reaching an intended thickness by repeating the steps from (c-1) to (c-4).

4. The method as recited in claim 2, wherein the silicon-containing gas is SiH₄ gas.

5. The method as recited in claim 1, wherein the metal barrier layer is made of such material as titanium nitride (TiN).

6. The method as recited in claim 1, wherein the conductive material is planarized by employing a chemical mechanical polishing process or an etch-back process.

7. The method as recited in claim 1, wherein the etch-back process is performed until the conductive material is planarized to an upper surface level of the metal barrier layer.
